(19) United States
(12) Patent Application Publication
(10) Pub. No.: US 2026/0116809 A1
(43) Pub. Date: Apr. 30, 2026

(54) GLASS ARTICLE, DISPLAY DEVICE INCLUDING THE SAME, AND ELECTRONIC DEVICE

(71) Applicant: Samsung Display Co., LTD., Yongin-si (KR)

(72) Inventors: Hoi Kwan LEE, Yongin-si (KR); Sung Won KIM, Yongin-si (KR); Sang Duk LEE, Yongin-si (KR); Jun Yeub LEE, Yongin-si (KR)

(21) Appl. No.: 19/225,210

(22) Filed: Jun. 2, 2025

(30) Foreign Application Priority Data
Oct. 28, 2024 (KR) 10-2024-0148559

(51) Int. Cl. C03C 3/091; B32B 7/12; B32B 17/06; C03C 3/064; C03C 3/089; H05K 5/03

(52) U.S. Cl. CPC C03C 3/091; B32B 7/12; B32B 17/06; C03C 3/064; C03C 3/089; H05K 5/03; B32B 2307/54; B32B 2307/7376; B32B 2457/202

(57) ABSTRACT

A display device includes a display panel including a plurality of pixels, a cover window located on the display panel, and an optically clear bonding layer located between the display panel and the cover window, where the cover window includes, as a glass composition, 45 to 60 mol % SiO₂, greater than 35 and equal to or less than 45 mol % B₂O₃, 3 to less than 9 mol % Na₂O, and greater than 0 to less than 8 mol % Al₂O₃ based on total content of the cover window.

This application claims priority to Korean Patent Application No. 10-2024-0148559, filed on Oct. 28, 2024, and all the benefits accruing therefrom under 35 U.S.C. § 119, the content of which in its entirety is herein incorporated by reference.

### BACKGROUND

### 1. Field

The present disclosure relates to a glass composition, a glass article manufactured from the same, and a display device.

### 2. Description of the Related Art

A glass article is widely used in electronic devices including display devices, building materials, and the like. For example, the glass article is applied to a substrate of a flat panel display device, such as a liquid crystal display (LCD), an organic light emitting display (OLED) or an electrophoretic display, or to a cover window for protecting the display device.

As portable electronic devices such as smart phones and tablet PCs increase, glass articles applied to the portable electronic devices are frequently exposed to external impact. Therefore, it is required to develop a glass article that is thin for portability and can withstand external impact.

Recently, research has been conducted on a display device that can be folded for user convenience. The glass article applied to a foldable display device may be required to have a small thickness to alleviate bending stress when the display device is folded and at the same time have sufficient strength to withstand external impact. Accordingly, attempts have been made to improve the strength of the thin glass article by changing the component ratio of a composition of the glass article and the conditions of a manufacturing process.

### SUMMARY

Aspects of the present disclosure provide a glass composition having a novel composition ratio, a glass article manufactured from the same, and a display device including the glass article.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, a glass article includes as a glass composition, 45 to 60 mole percents (mol %) SiO₂, greater than 35 and equal to or less than 45 mol % B₂O₃, 3 to less than 9 mol % Na₂O, and greater than 0 to less than 8 mol % Al₂O₃ based on total content of the glass article.

In an embodiment, a ratio of the SiO₂ content to the B₂O₃ content may be 1 or greater.

In an embodiment, a difference between the B₂O₃ content and the Na₂O content may be 40 mol % or less.

In an embodiment, a ratio of the Na₂O content to the Al₂O₃ content may be greater than 1.

In an embodiment, the glass article may further include K₂O in an amount of greater than 0 to 5 mol %.

In an embodiment, a ratio of the sum of the Na₂O content and the K₂O content to the Al₂O₃ content may be greater than 1.

In an embodiment, a thickness of the glass article may be 50 to 100 micrometers (μm).

In an embodiment, an elastic modulus of the glass article may be 30 to 55 gigapascals (GPa).

According to one or more embodiments of the present disclosure, a glass composition includes 45 to 60 mol % SiO₂, greater than 35 and equal to or less than 45 mol % B₂O₃, 3 to less than 9 mol % Na₂O, and greater than 0 to less than 8 mol % Al₂O₃ based on total content of the glass composition.

In an embodiment, a ratio of the SiO₂ content to the B₂O₃ content may be 1 or greater.

In an embodiment, a difference between the B₂O₃ content and the Na₂O content may be 40 mol % or less.

In an embodiment, a ratio of the Na₂O content to the Al₂O₃ content may be greater than 1.

In an embodiment, the glass composition may further include K₂O in an amount of greater than 0 to 5 mol %.

In an embodiment, a ratio of the sum of the Na₂O content and the K₂O content to the Al₂O₃ content may be greater than 1.

According to one or more embodiments of the present disclosure, a display device includes a display panel including a plurality of pixels, a cover window located on the display panel, and an optically clear bonding layer located between the display panel and the cover window, where the cover window includes, as a glass composition, 45 to 60 mol % SiO₂, greater than 35 and equal to or less than 45 mol % B₂O₃, 3 to less than 9 mol % Na₂O, and greater than 0 to less than 8 mol % Al₂O₃ based on total content of the cover window.

In an embodiment, a ratio of the SiO₂ content to the B₂O₃ content may be 1 or greater.

In an embodiment, a difference between the B₂O₃ content and the Na₂O content may be 40 mol % or less, and a ratio of the Na₂O content to the Al₂O₃ content may be greater than 1.

In an embodiment, the display device may further include K₂O in an amount of greater than 0 to 5 mol %, where a ratio of the sum of the Na₂O content and the K₂O content to the Al₂O₃ content may be greater than 1.

In an embodiment, the cover window may have a thickness of 50 to 100 μm.

In an embodiment, the cover window may have an elastic modulus of 30 to 55 GPa.

According to one or more embodiments of the present disclosure, an electronic device includes a display device configured to provide an image, and a processor configured to provide an image data signal to the display device, where the display device includes a display panel including a plurality of pixels, a cover window located on the display panel, and an optically clear bonding layer located between the display panel and the cover window. The cover window includes, as a glass composition, 45 to 60 mol % SiO₂, greater than 35 and equal to or less than 45 mol % B₂O₃, 3 to less than 9 mol % Na₂O, and greater than 0 to less than 8 mol % Al₂O₃ based on total content of the cover window.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of glass articles according to various embodiments;

FIG. 2 is a perspective view illustrating an unfolded state of a display device to which a glass article according to an embodiment is applied;

FIG. 3 is a perspective view illustrating a folded state of the display device of FIG. 2;

FIG. 4 is a cross-sectional view illustrating an example in which a glass article according to an embodiment is applied as a cover window of a display device;

FIG. 5 is a cross-sectional view of a flat plate-shaped glass article according to an embodiment;

FIG. 6 is a graph illustrating a stress profile of the glass article according to the embodiment of FIG. 5;

FIG. 7 is a flowchart illustrating operations in a process of manufacturing a glass article according to an embodiment; and

FIG. 8 is a schematic diagram illustrating a series of operations from a cutting operation to a post-tempering surface polishing operation of FIG. 7.

FIG. 9 is a block diagram of an electronic device according to one embodiment of the present disclosure.

FIG. 10 is a schematic diagram of an electronic device according to various embodiments of the present disclosure.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, embodiments will be described with reference to the accompanying drawings.

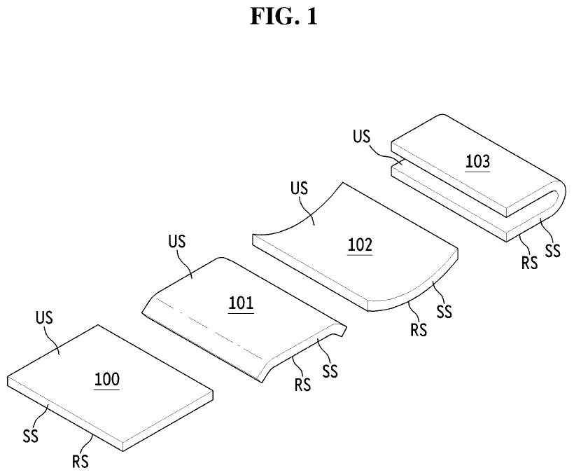

FIG. 1 is a perspective view of glass articles according to various embodiments.

Glass is used as a cover window for protecting a display, as a substrate for a display panel, as a substrate for a touch panel, as an optical member such as a light guide plate, etc. in electronic devices including displays such as tablet PCs, notebook PCs, smartphones, electronic books, televisions and PC monitors as well as refrigerators and washing machines including display screens. The glass may also be used for cover glass of vehicle dashboards, cover glass of solar cells, building interior materials, and windows of buildings or houses.

Glass is required to have high strength. For example, glass for windows is required to be thin to have high transmittance and lightweight properties, but also required to be strong enough not to be easily broken by an external impact. Glass with increased strength may be produced using a method such as chemical tempering or thermal tempering. Examples of tempered glass having various shapes are illustrated in FIG. 1.

Hereinafter, the present disclosure describes glass articles, but the glass articles may refer to the same as the glass as described above.

Referring to FIG. 1, in an embodiment, a glass article 100 may be in the shape of a flat sheet or a flat plate. In other embodiments, glass articles 101 through 103 may have a three-dimensional (3D) shape including a bent portion. For example, a glass article may include a flat portion whose edges are bent (see ‘101’), may be curved overall (see ‘102’), or may be folded (see ‘103’). Alternatively, the glass article 100 may be shaped like a flat sheet or a flat plate but may have flexibility so that it can be folded, stretched, or rolled.

The glass articles 100 through 103 may have a rectangular planar shape. However, the glass articles 100 through 103 are not limited to the rectangular planar shape and may also have various planar shapes such as a rectangle with rounded corners, a square, a circle, and an oval. In the following embodiments, a flat plate having a rectangular planar shape will be described as an example of the glass articles 100 through 103. However, it is clear that the present disclosure is not limited thereto.

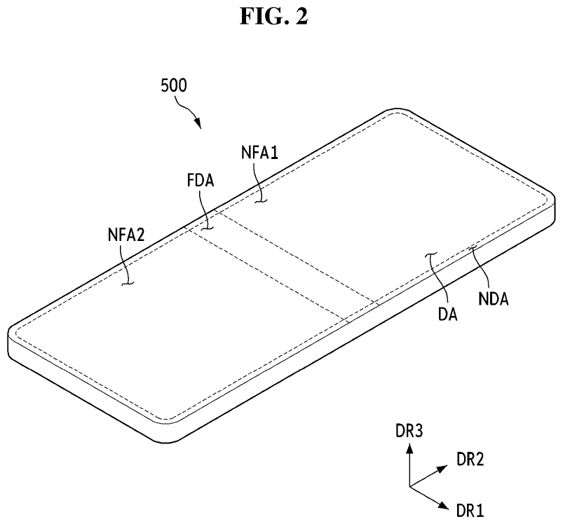

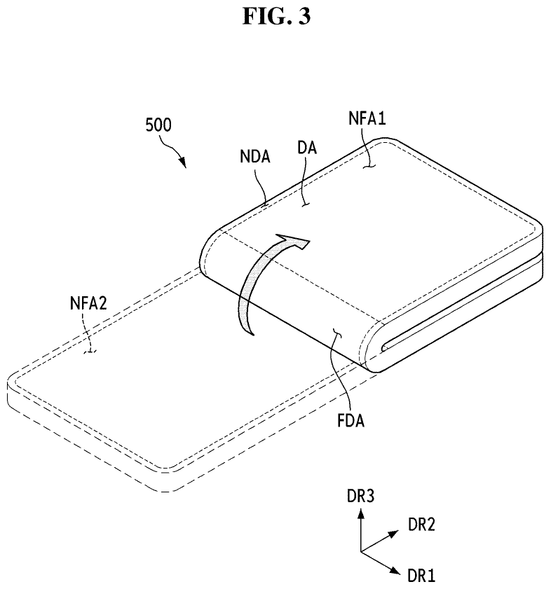

FIG. 2 is a perspective view illustrating an unfolded state of a display device 500 to which a glass article according to an embodiment is applied. FIG. 3 is a perspective view illustrating a folded state of the display device 500 of FIG. 2.

Referring to FIGS. 2 and 3, the display device 500 according to the embodiment may be a foldable display device. As will be described later, the glass article 100 of FIG. 1 may be applied to the display device 500 as a cover window. The glass article 100 may have flexibility so that it can be folded.

In FIGS. 2 and 3, a first direction DR1 may be a direction parallel to a side of the display device 500 in a plan view, for example, a horizontal direction of the display device 500. A second direction DR2 may be a direction parallel to another side of the display device 500 in contact with the above side in a plan view, for example, a vertical direction of the display device 500. A third direction DR3 may be a thickness direction of the display device 500.

In an embodiment, the display device 500 may be rectangular in a plan view. The display device 500 may be shaped like a rectangle with perpendicular corners or a rectangle with rounded corners in a plan view. The display device 500 may include two short sides located in the first direction DR1 and two long sides located in the second direction DR2 in a plan view.

The display device 500 includes a display area DA and a non-display area NDA. The shape of the display area DA may correspond to the shape of the display device 500 in a plan view. For example, when the display device 500 is rectangular in a plan view, the display area DA may also be rectangular.

The display area DA may be an area including a plurality of pixels to display an image. The pixels may be arranged in a matrix direction. Each of the pixels may be shaped like a rectangle, a rhombus, or a square in a plan view. However, the present disclosure is not limited thereto. For example, each of the pixels may also be shaped like a quadrilateral other than a rectangle, a rhombus or a square, a polygon other than a quadrilateral, a circle, or an oval in a plan view.

The non-display area NDA may be an area not displaying an image because it does not include pixels. The non-display area NDA may be located around the display area DA. The non-display area NDA may surround the display area DA. However, the present disclosure is not limited thereto. The display area DA may also be partially surrounded by the non-display area NDA.

In an embodiment, the display device 500 may maintain both the folded state and the unfolded state. The display device 500 may be folded in an in-folding manner in which the display area DA is located inside as illustrated in FIG. 3. When the display device 500 is folded in the in-folding manner, portions of an upper surface of the display device 500 may face each other. Alternatively, the display device 500 may be folded in an out-folding manner in which the display area DA is located outside. When the display device 500 is folded in the out-folding manner, portions of a lower surface of the display device 500 may face each other.

In an embodiment, the display device 500 may be a foldable device. In the present specification, the term “foldable device” is used to refer to devices that can be folded, including not only a folded device but also a device that can have both the folded state and the unfolded state. In addition, folding typically includes folding at an angle of about 180 degrees. However, the present disclosure is not limited thereto, and folding at an angle of more than or less than 180 degrees, such as folding at an angle of 90 to less than 180 degrees or an angle of 120 to less than 180 degrees may also be understood as folding. Furthermore, even an incompletely folded state may also be referred to as the folded state if it is not the unfolded state. For example, even a folded state at an angle of 90 degrees or less may be expressed as the folded state to distinguish it from the unfolded state as long as a maximum folding angle is 90 degrees or more. The radius of curvature at the time of folding may be 5 millimeters (mm) or less, preferably, 1 to 2 mm or about 1.5 mm. However, the present disclosure is not limited thereto.

In an embodiment, the display device 500 may include a folding area FDA, a first non-folding area NFA1, and a second non-folding area NFA2. The folding area FDA may be an area in which the display device 500 is folded, and the first non-folding area NFA1 and the second non-folding area NFA2 may be areas in which the display device 500 is not folded.

The first non-folding area NFA1 may be located on a side, e.g., an upper side of the folding area FDA. The second non-folding area NFA2 may be located on the other side, e.g., a lower side of the folding area FDA. The folding area FDA may be an area bent with a predetermined curvature.

In an embodiment, the folding area FDA of the display device 500 may be set at a specific position. In the display device 500, one folding area FDA or two or more folding areas FDA may be set at a specific position. In an embodiment, the folding area FDA may not be limited to a specific position in the display device 500 but may be freely set in various areas.

In an embodiment, the display device 500 may be folded in the second direction DR2. As a result, a length of the display device 500 in the second direction DR2 may be reduced to about half. Therefore, a user can easily carry the display device 500.

In an embodiment, the direction in which the display device 500 is folded is not limited to the second direction DR2. For example, the display device 500 may also be folded in the first direction DR1. In this case, a length of the display device 500 in the first direction DR1 may be reduced to about half.

In the drawings, each of the display area DA and the non-display area NDA overlaps the folding area FDA, the first non-folding area NFA1, and the second non-folding area NFA2. However, the present disclosure is not limited thereto. For example, each of the display area DA and the non-display area NDA may overlap at least one of the folding area FDA, the first non-folding area NFA1, and the second non-folding area NFA2.

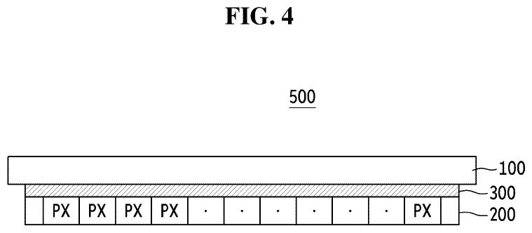

FIG. 4 is a cross-sectional view illustrating an example in which a glass article 100 according to an embodiment is applied as a cover window of a display device 500.

Referring to FIG. 4, the display device 500 may include a display panel 200, the glass article 100 located on the display panel 200 and serving as a “cover window”, and an optically clear bonding layer 300 located between the display panel 200 and the glass article 100 to bond the display panel 200 and the glass article 100 together.

The display panel 200 may be, for example, a self-luminous display panel such as an organic light emitting display panel (OLED), an inorganic electroluminescent (EL) display panel, a quantum dot light emitting display panel (QED), a micro-light emitting diode (LED) display panel, a nano-LED display panel, a plasma display panel (PDP), a field emission display panel (FED) or a cathode ray tube (CRT) display panel or may be a light receiving display panel such as a liquid crystal display (LCD) panel or an electrophoretic display (EPD) panel.

The display panel 200 may include a plurality of pixels PX and may display an image using light emitted from each pixel PX. The display device 500 may further include a touch member (not illustrated). In an embodiment, the touch member may be internalized in the display panel 200. For example, the touch member may be directly formed on a display member of the display panel 200 so that the display panel 200 itself can perform a touch function. In an embodiment, the touch member may be manufactured separately from the display panel 200 and then attached to an upper surface of the display panel 200 by an optically clear bonding layer.

The glass article 100 is located on the display panel 200 to protect the display panel 200. The glass article 100 may be larger in size than the display panel 200. Thus, side surfaces of the glass article 100 may protrude further out than side surfaces of the display panel 200, but the present disclosure is not limited to this case. The display device 500 may further include a print layer (not illustrated) located on at least one surface of the glass article 100 at edges of the glass article 100. The print layer may prevent a bezel area of the display device 500 from being visible from the outside and, in some cases, may perform a decorative function.

The optically clear bonding layer 300 is located between the display panel 200 and the glass article 100. The optically clear bonding layer 300 fixes the glass article 100 on the display panel 200. The optically clear bonding layer 300 may include an optical clear adhesive (OCA) or an optical clear resin (OCR).

The tempered glass article 100 described above will now be described in more detail.

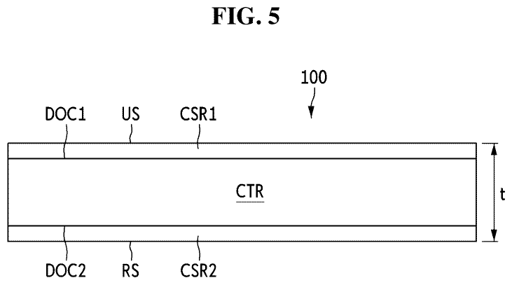

FIG. 5 is a cross-sectional view of a flat plate-shaped glass article 100 according to an embodiment.

Referring to FIG. 5, the glass article 100 may include a first surface US, a second surface RS, and side surfaces. The first surface US and the second surface RS of the flat plate-shaped glass article 100 are main surfaces having a large area, and the side surfaces are outer surfaces connecting the first surface US and the second surface RS.

The first surface US and the second surface RS face each other in the thickness direction. When the glass article 100 serves to transmit light like a cover window of a display, the light may usually be incident on any one of the first surface US and the second surface RS and then transmitted to the other surface.

A thickness t of the glass article 100 is defined as a distance between the first surface US and the second surface RS. The thickness t of the glass article 100 may be, but is not limited to, 100 μm or less, preferably, 20 to 100 μm. In an embodiment, the thickness t of the glass article 100 may be 80 μm or less. In an embodiment, the thickness t of the glass article 100 may be about 75 μm or less. In an embodiment, the thickness t of the glass article 100 may be about 70 μm or less. In an embodiment, the thickness t of the glass article 100 may be about 60 μm or less. In an embodiment, the thickness t of the glass article 100 may be about 65 μm or less. In an embodiment, the thickness t of the glass article 100 may be about 50 μm or less. In an embodiment, the thickness t of the glass article 100 may be about 30 μm or less. In some specific embodiments, the thickness t of the glass article 100 may be in the range of 20 to 50 μm or may have a value of about 30 μm. The glass article 100 may have a uniform thickness t. However, the present disclosure is not limited thereto, and the glass article 100 may also have a different thickness t in each region.

The glass article 100 may be tempered to have a predetermined stress profile therein. The glass article 100 after being tempered better prevents crack generation, crack propagation, and breakage due to external impact than the glass article 100 before being tempered. The glass article 100 tempered through a tempering process may have various stresses in different regions. For example, compressive regions CSR1 and CSR2 in which compressive stress acts may be located near the surfaces of the glass article 100, that is, near the first surface US and the second surface RS, and a tensile region CTR in which tensile stress acts may be located inside the glass article 100. A stress value may be zero at boundaries DOC1 and DOC2 between the compressive regions CSR1 and CSR2 and the tensile region CTR. The compressive stress in one compressive region CSR1 or CSR2 may have a different stress value according to the position (i.e., the depth from the surface). In addition, the tensile region CTR may have a different stress value according to the depth from the surface US or RS.

Positions of the compressive regions CSR1 and CSR2 in the glass article 100, stress profiles in the compressive regions CSR1 and CSR2, and compressive energies of the compressive regions CSR1 and CSR2 or tensile energy of the tensile region CTR may greatly affect mechanical properties such as surface strength of the glass article 100.

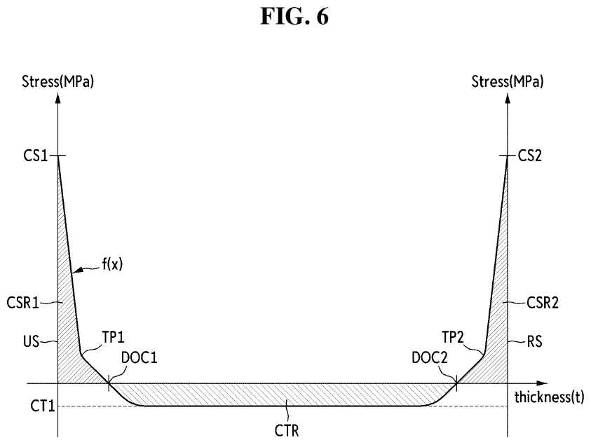

FIG. 6 is a graph illustrating a stress profile of the glass article 100 according to the embodiment of FIG. 5. In the graph of FIG. 6, the x axis represents the thickness direction of the glass article 100. In FIG. 6, compressive stress is represented by a positive value, and tensile stress is represented by a negative value. In the present specification, the magnitude of the compressive/tensile stress denotes the magnitude of an absolute value regardless of the sign of the value.

Referring to FIG. 6, the glass article 100 includes a first compressive region CSR1 extending (or expanding) from the first surface US to a first compression depth DOC1 and a second compressive region CSR2 extending (or expanding) from the second surface RS to a second compression depth DOC2. The tensile region CTR is located between the first compression depth DOC1 and the second compression depth DOC2. In the overall stress profile of the glass article 100, regions on both surface sides US and RS may be symmetrical to each other with respect to a center of the thickness (t) direction. Although not illustrated in FIG. 6, compressive regions and a tensile region may also be located in a similar manner between facing side surfaces of the glass article 100.

The first compressive region CSR1 and the second compressive region CSR2 resist external impact to prevent generation of cracks in the glass article 100 or breakage of the glass article 100. The greater the maximum compressive stresses CS1 and CS2 of the first and second compressive regions CSR1 and CSR2, the greater the strength of the glass article 100. Since external impact is usually transmitted through the surfaces of the glass article 100, it is advantageous in terms of durability to have the maximum compressive stresses CS1 and CS2 at the surfaces of the glass article 100. In this regard, the compressive stresses of the first compressive regions CSR1 and the second compressive region CSR2 tend to be greatest at the surfaces and gradually decrease in a direction toward the inside of the glass article 100.

The first compression depth DOC1 and the second compression depth DOC2 prevent cracks or grooves formed in the first and second surfaces US and RS from propagating to the tensile region CTR inside the glass article 100. The greater the first and second compression depths DOC1 and DOC2, the better the propagation of cracks can be prevented. Points corresponding to the first compression depth DOC1 and the second compression depth DOC2 correspond to the boundaries between the compressive regions CSR1 and CSR2 and the tensile region CTR and have a stress value of 0.

Throughout the glass article 100, the tensile stress of the tensile region CTR may be balanced with the compressive stresses of the compressive regions CSR1 and CSR2. That is, the total compressive stress (i.e., compressive energy) in the glass article 100 may be equal to the total tensile stress (i.e., tensile energy). The stress energy accumulated in one region having a predetermined width in the thickness (1) direction in the glass article 100 may be calculated by integrating a stress profile. When the stress profile in the glass article 100 having a thickness of t is represented by a function f(x), the following equation may be established.

$${\int }_{0}^{t} f ( x ) dx = 0. \qquad ( 1 )$$

As the magnitude of the tensile stress inside the glass article 100 increases, fragments may be violently expelled when the glass article 100 is broken, and crushing may occur from inside the glass article 100. The maximum tensile stress that meets the fragility criteria of the glass article 100 is not limited to but may satisfy the following relation.

$${CT}_{1} \leq - 38.7 \times ln ( t ) + 48.2 . \qquad ( 2 )$$

In some embodiments, maximum tensile stress CT1 may be 100 megapascals (Mpa) or less or may be 85 MPa or less. The maximum tensile stress CT1 of 75 MPa or more may improve mechanical properties such as strength. In an embodiment, the maximum tensile stress CT1 may be, but is not limited to, 75 to 85 MPa.

The maximum tensile stress CT1 of the glass article 100 may be generally located in a central portion of the glass article 100 in the thickness (t) direction. For example, the maximum tensile stress CT1 of the glass article 100 may be located at a depth of 0.4 to 0.6 t, at a depth of 0.45 to 0.55 t, or at a depth of about 0.5 t.

Large compressive stress and compression depths DOC1 and DOC2 may be advantageous in increasing the strength of the glass article 100. However, as the compressive energy increases, the tensile energy may also increase, thereby increasing the maximum tensile stress CT1. In order for the glass article 100 to meet the fragility criteria while having high strength, the stress profile may be adjusted to increase the maximum compressive stresses CS1 and CS2 and the compression depths DOC1 and DOC2 and reduce the compressive energy. To this end, the glass article 100 may be manufactured using a glass composition including specific components in a predetermined ratio. Depending on the composition ratio of the components included in the glass composition, the manufactured glass article 100 may have excellent strength and, at the same time, may have flexible nature and physical properties that make it applicable to a foldable display device.

According to an embodiment, the glass composition that forms the glass article 100 may include a ternary glass composition containing 45 to 60 mol % SiO₂, greater than 35 and equal to or less than 45 mol % B₂O₃, and 3 to less than 9 mol % Na₂O based on total content of the glass composition. In addition, the glass composition may include a quaternary glass composition further containing greater than 0 to less than 8 mol % Al₂O₃. In addition, the glass composition may include a quinary glass composition further containing greater than 0 to 5 mol % K₂O. In another embodiment, the B₂O₃ content may have 36 to 45 mol % and the Na₂O content may have 3 to 8 mol %. In still another embodiment, the B₂O₃ content may have 37 to 45 mol % and the Na₂O content may have 3 to 7 mol %.

Each component of the glass composition will now be described in more detail.

SiO₂ may serve to form the framework of glass, increase chemical durability (e.g., chemical resistance), and reduce generation of cracks due to scratches (indentations) on the glass surface. SiO₂ may be a network former oxide that forms a network of glass, and the glass article 100 manufactured to include SiO₂ may have a reduced coefficient of thermal expansion and improved mechanical strength. To fully perform the above roles, SiO₂ may be contained in an amount of 45 mol % or more. To exhibit sufficient meltability, SiO₂ may be contained in the glass composition in an amount of 60 mol % or less.

B₂O₃ may form glass with a coordination number of 3 to reduce bonding strength, i.e., viscosity. Accordingly, the glass transition temperature and elastic modulus of the glass may be reduced, thereby improving the folding and unfolding characteristics of the glass article 100. That is, as the elastic modulus of the glass is reduced, the stress applied to a lower portion of the glass article during folding and unfolding is reduced, thereby improving the bending characteristics of the glass article. B₂O₃ may reduce the glass transition temperature and the elastic modulus when contained in an amount of greater than 35 mol %. B₂O₃ may be contained in an amount of 45 mol % or less to prevent a reduction in chemical durability.

Na₂O serves to form surface compressive stress through ion exchange and improve meltability of glass. Na₂O may form non-bridging oxygen in a SiO₂ network structure by forming an ionic bond with oxygen of SiO₂ that forms the network structure. An increase in non-bridging oxygen may improve the flexibility of the network structure and may cause the glass article 100 to have physical properties that make it applicable to a foldable display device. Na₂O content of 3 mol % or more may facilitate ion exchange during a chemical tempering process, thereby forming surface compressive stress and improving the meltability of the glass. Na₂O content of less than 9 mol % may prevent an increase in the elastic modulus of the glass article 100.

As described above, the glass article 100 manufactured using the glass composition according to the embodiment may have characteristics and physical properties that make it applicable to a foldable display device. For example, the glass article 100 may have flexibility so that it can be folded and unfolded and may have strength and chemical properties sufficient to make it applicable as a cover window of the display device 500. A network structure formed by the glass composition containing SiO₂ and B₂O₃ may turn into a flexible network structure by the addition of Na₂O. Due to the addition of Na₂O, Na ions may form an ionic bond with oxygen between bonds that form the network structure, for example, bonds between SiO₂, thereby increasing non-bridging oxygen. An increase in non-bridging oxygen within the network structure means that the bonds of the network structure are broken or open, and the network structure of the glass may have flexibility. The glass composition may contain Na₂O in an amount of 3 to less than 9 mol % so that the manufactured glass article 100 can have sufficient flexibility.

Since the glass composition contains an excessive amount of B₂O₃, chemical durability may be reduced. To compensate for this, a ratio of SiO₂ content to B₂O₃ content (SiO₂/B₂O₃) in the glass composition may be adjusted to 1 or greater, thereby preventing a reduction in chemical durability. For example, the SiO₂ content in the glass composition may be greater than or equal to the B₂O₃ content. If the ratio of the SiO₂ content to the B₂O₃ content is 1 or greater, vitrification is possible, and a reduction in chemical durability can be prevented.

According to an embodiment, a difference between the B₂O₃ content and the Na₂O content (B₂O₃—Na₂O) in the glass composition may be 40 mol % or less. For example, the B₂O₃ content in the glass composition may be greater than the Na₂O content, and the difference may be 40 mol % or less. If the difference between the B₂O₃ content and the Na₂O content (B₂O₃—Na₂O) is 40 mol % or less, a reduction in the chemical durability of the glass article 100 can be prevented.

The glass composition including the ternary system according to the embodiment described above may improve the folding and unfolding characteristics of the glass article 100 by reducing the elastic modulus of the glass article 100 while enabling the glass article 100 to have the strength and flexibility required for a foldable display device. In addition, the content of each component may be adjusted to prevent a reduction in the chemical durability of the glass article. The glass composition including the ternary system described above may be composed of only three components, for example, SiO₂, B₂O₃ and Na₂O and may not include other components.

In addition, the glass composition may be a quaternary glass composition further containing Al₂O₃. Al₂O₃ may be an intermediate oxide that forms a bond with SiO₂ forming a network structure. Al₂O₃ may act as an active component that improves ion exchange performance during chemical tempering and increases surface compressive stress after the tempering. In addition, Al₂O₃ may increase chemical durability and improve meltability. When contained in an amount of greater than 1 mol %, Al₂O₃ may effectively perform the above functions. In addition, Al₂O₃ content of less than 8 mol % may prevent an increase in the elastic modulus of the glass article 100.

According to an embodiment, a ratio of Na₂O content to Al₂O₃ content (Na₂O/Al₂O₃) in the glass composition may be greater than 1. For example, the Na₂O content in the glass composition may be greater than the Al₂O₃ content. Na₂O may improve the durability of the glass article 100 by acting to form an AlO₆ structure of Al₂O₃ into a tetrahedral structure of AlO₄. In addition, the remaining Na₂O may improve the chemical durability of glass by acting to form a BO₃ structure of B₂O₃ into a tetrahedral structure of BO₄. Therefore, when the ratio of the Na₂O content to the Al₂O₃ content (Na₂O/Al₂O₃) is greater than 1, the chemical durability of the glass article 100 can be improved.

Since the glass composition including the quaternary system according to the embodiment described above further contains Al₂O₃, it can further increase the chemical durability of the glass article 100, in addition to the effect of the ternary system. The glass composition including the quaternary system described above may be composed of only four components, for example, SiO₂, B₂O₃, Na₂O and Al₂O₃ and may not include other components.

According to an embodiment, the glass composition may be a quinary glass composition further containing K₂O. K₂O may increase the compressive stress of glass by exchanging (e.g., replacing) Na ions for K ions in a chemical tempering process. Accordingly, K₂O may contribute to implementing a flexible glass article 100 by improving the folding reliability and bending reliability of the glass article. K₂O and Na₂O may increase an ion exchange rate during the chemical tempering process due to a mixed alkali effect. Therefore, the addition of K₂O may reduce the chemical tempering process time. K₂O may significantly perform the above function when contained in an amount of greater than 0 mol %. However, K₂O content may be 5 mol % or less in order to prevent a reduction in the elastic modulus of the glass article 100.

According to an embodiment, a ratio of the sum of Na₂O content and K₂O content to Al₂O₃ content ((Na₂OK₂O)/Al₂O₃) in the glass composition may be greater than 1. For example, the sum of the Na₂O content and the K₂O content in the glass composition may be greater than the Al₂O₃ content. In addition to Na₂O described above, K₂O may improve the durability of the glass article 100 by acting to form the AlO₆ structure of Al₂O₃ into the tetrahedral structure of AlO₄, and the remaining K₂O may improve the chemical durability of glass by acting to form the BO₃ structure of B₂O₃ into the tetrahedral structure of BO₄. Therefore, when the ratio of the sum of the Na₂O content and the K₂O content to the Al₂O₃ content ((Na₂OK₂O)/Al₂O₃) is greater than 1, the chemical durability of the glass article 100 can be improved.

Since the glass composition including the quinary system according to the embodiment described above further contains K₂O, it can reduce the chemical tempering process time of the glass article 100 and further increase the chemical durability of the glass article 100, in addition to the effect of the quaternary system. The glass composition including the quinary system described above may be composed of only five components, for example, SiO₂, B₂O₃, Na₂O, Al₂O₃ and K₂O and may not include other components.

The glass composition having the above composition may be molded into the shape of plate glass using various methods known in the art. Once molded into the plate glass shape, the glass composition may be further processed to produce the glass article 100 that can be applied to the display device 500. However, the present disclosure is not limited thereto, and the glass composition may also not be molded into the plate glass shape but may be directly molded into the glass article 100 applicable to a product without an additional molding process.

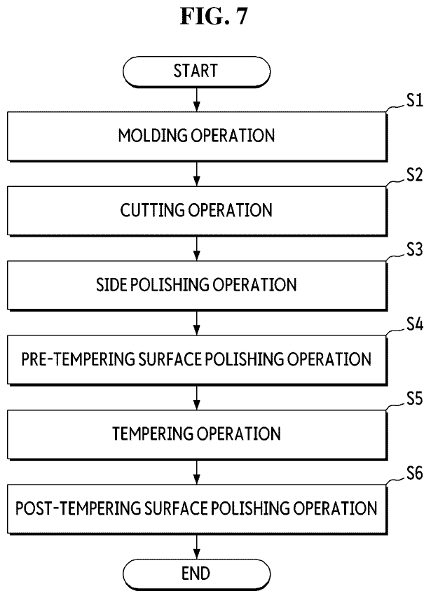

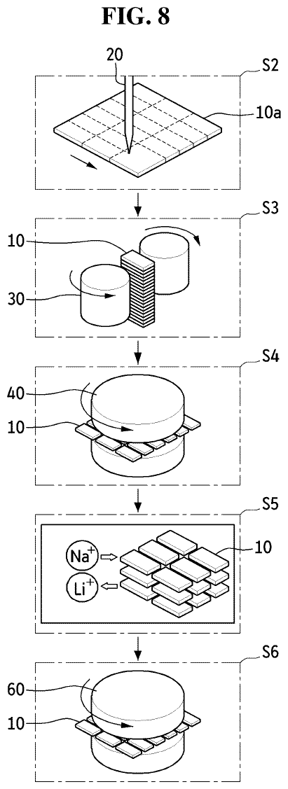

FIG. 7 is a flowchart illustrating operations in a process of manufacturing a glass article according to an embodiment. FIG. 8 is a schematic diagram illustrating a series of operations from a cutting operation to a post-tempering surface polishing operation of FIG. 7.

Referring to FIGS. 7 and 8, a method of manufacturing a glass article 100 may include a molding operation (operation S1), a cutting operation (operation S2), a side polishing operation (operation S3), a pre-tempering surface polishing operation (operation S4), a tempering operation (operation S5), and a post-tempering surface polishing operation (operation S6).

The molding operation (operation S1) may include preparing a glass composition and molding the glass composition. The glass composition may have the above-described composition and components, which will not be described in detail here. The glass composition may be molded into the shape of plate glass by a method such as a float process, a fusion draw process, or a slot draw process.

The glass molded into a flat plate shape may be cut through the cutting operation (operation S2). The glass molded into the flat plate shape may have a size different from the size applied to a final glass article 100. For example, the glass in the state of a large-area substrate as mother glass 10a in units of a mother substrate including a plurality of glass articles may be molded and then cut into a plurality of cells to produce a plurality of glass articles. For example, although the final glass article 100 has a size of about 6 inches, the glass may be molded to a size (e.g., 120 inches) several to hundreds of times the size of the final glass article 100 and then cut to produce 20 flat plate shapes at once. This can improve process efficiency as compared with when individual glass articles are molded separately. In addition, even when glass corresponding to the size of one glass article is molded, if the final glass article has various planar shapes, a desired shape may be formed through the cutting process.

The cutting of the mother glass 10a may be performed using a cutting knife 20, a cutting wheel, a laser, or the like.

The glass cutting operation (operation S2) may be performed before the glass tempering operation (operation S5). The mother glass 10a can be tempered and then cut into cells of the final glass article size. In this case, however, cut surfaces (e.g., side surfaces) of the glass may not be tempered. Therefore, it is desirable to perform the tempering operation (operation S5) after completing the cutting operation (operation S2).

A pre-tempering polishing operation may be performed between the glass cutting operation (operation S2) and the glass tempering operation (operation S5). The polishing operation may include the side polishing operation (operation S3) and the pre-tempering surface polishing operation (operation S4). In an embodiment, the side polishing operation (operation S3) may be performed before the pre-tempering surface polishing operation (operation S4), but this order can be reversed.

The side polishing operation (operation S3) is an operation of polishing side surfaces of the glass cells 10 into which the mother glass 10a has been cut. In the side polishing operation (operation S3), the side surfaces of the glass cells 10 may be polished to become smooth. In addition, the side surfaces of the glass cells 10 may become uniform through the side polishing operation (operation S3). More specifically, each glass cell 10 may include one or more cut surfaces. Some of the glass cells 10 may have two cut surfaces out of four side surfaces. Some other glass cells 10 may have three cut surfaces out of four side surfaces. Some other glass cells 10 may have all four side surfaces as cut surfaces. Surface roughness may be different between a cut side surface and an uncut side surface. The surface roughness may also be different even between cut surfaces. Therefore, each side surface may be polished through the side polishing operation (operation S3) to have a uniform surface roughness. Furthermore, if there is a small crack in a side surface, it may also be removed through the side polishing operation (operation S3).

The side polishing operation (operation S3) may be simultaneously performed on the glass cells 10. That is, the glass cells 10 may be simultaneously polished in a state where they are stacked.

The side polishing operation (operation S3) may be performed by a mechanical polishing method or a chemical mechanical polishing method using a polishing device 30. In an embodiment, two facing side surfaces of each glass cell 10 may be simultaneously polished, and then the other two facing side surfaces may be simultaneously polished. However, the present disclosure is not limited thereto.

The pre-tempering surface polishing operation (operation S4) may be performed to ensure that each glass cell 10 has an even surface. The pre-tempering surface polishing operation (operation S4) may be performed on the glass cells 10 one by one. However, if a chemical mechanical polishing device 40 is sufficiently larger than the glass cells 10, the glass cells 10 may be arranged horizontally and then may be simultaneously surface-polished.

The pre-tempering surface polishing operation (operation S4) may be performed by a chemical mechanical polishing method. Specifically, a first surface and a second surface of each glass cell 10 are polished using a chemical mechanical polishing device 40 and polishing slurry. The first surface and the second surface may be polished simultaneously, or one surface may be polished first, and then the other surface may be polished.

The tempering operation (operation S5) is performed after the pre-tempering polishing operation (operation S4). The tempering operation (operation S5) may be performed as chemical tempering and/or thermal tempering. In the case of a thin glass cell 10 having a thickness of 2 mm or less, by extension, about 0.75 mm or less, chemical tempering may be suitably applied for precise stress profile control.

After the tempering operation (operation S5), the post-tempering surface polishing operation (operation S6) may be further performed optionally. The post-tempering surface polishing operation (operation S6) may serve to remove fine cracks in the surfaces of the tempered glass cells 10 and to control the compressive stress of the first and second surfaces of the tempered glass cells 10. For example, in a floating method which is one of the plate glass manufacturing methods, a glass composition is poured into a tin bath. In this case, a surface in contact with the tin bath and a surface not in contact with the tin bath may have different compositions. Accordingly, a difference in compressive stress between the surface in contact with the tin bath and the surface not in contact with the tin bath may occur after the tempering of the glass cells 10 (operation S5). The difference in compressive stress between the surface in contact with the tin bath and the surface not in contact with the tin bath can be reduced by removing the surface of each glass cell 10 to an appropriate thickness through polishing.

The post-tempering surface polishing process (operation S6) may be performed using a chemical mechanical polishing method. Specifically, the first and second surfaces of the tempered glass cells 10, which are the treated glass cells 10, are polished using a chemical mechanical polishing device 60 and polishing slurry. A polishing thickness may be adjusted in the range of, but not limited to, 100 to 1000 nanometers (nm). Polishing thicknesses of the first surface and the second surface may be the same or different.

Although not illustrated in the drawings, a shape machining process may be further performed as needed after the post-tempering surface polishing process (operation S6). For example, when the 3D glass articles 101 through 103 illustrated in FIG. 1 are to be manufactured, a 3D machining process may be performed after the post-tempering surface polishing process (operation S6) is completed.

The glass article 100 manufactured through the above-described process may include a component ratio similar to that of the glass composition. For example, the glass article 100 may include a ternary glass composition containing 45 to 60 mol % SiO₂, greater than 35 and equal to or less than 45 mol % B₂O₃, and 3 to less than 9 mol % Na₂O. In addition, the glass composition may include a quaternary glass composition further containing greater than 0 to less than 8 mol % Al₂O₃. In addition, the glass composition may include a quinary glass composition further containing greater than 0 to 5 mol % K₂O.

According to an embodiment, the glass article 100 manufactured from the glass composition described above may have a thickness of 100 μm or less, preferably 50 to 100 μm, to improve surface integrity characteristics. In addition, the glass article 100 may have an elastic modulus of 30 to 55 GPa.

Hereinafter, embodiments will be described in greater detail by way of Experimental Examples.

### Experimental Example 1: Manufacture of Ternary Glass Articles

Glass compositions having a ternary composition ratio of SiO₂, B₂O₃, and Na₂O were prepared according to Table 1 below, and then glass articles of SAMPLE #1 through SAMPLE #14 were manufactured. The glass article of each sample was manufactured to have a thickness of 50 μm.

The composition, elastic modulus, vitrification behavior, and chemical resistance of the glass article of each sample were measured and are shown in Table 1 below.

Here, the elastic modulus was checked by preparing a 10×20×3 cubic millimeters (mm³) specimen for each composition and checking the stress and strain of the specimen using an elastic modulus tester.

The vitrification behavior was indicated as ‘◯’ when a prepared glass composition was completely melted at a corresponding melting temperature and when the transmittance of the prepared glass composition manufactured into a glass article was 88% or higher. The number M in parentheses is a melting temperature, and the number A is an annealing temperature.

The chemical resistance was expressed as the relative transparency of a glass article when viewed with the naked eye after the glass article was stored in an atmosphere of room temperature and 80% humidity for more than 24 hours. As the transparency is greater, the chemical resistance is higher. ‘◯’ indicates that the entire glass article appears transparent, ‘Δ’ indicates that some parts appear cloudy, ‘X’ indicates that the entire glass article appears cloudy, ‘XX’ indicates that the glass article appears cloudier than X, and ‘XXX’ indicates that the glass article appears cloudier than XX.

TABLE 1

| | | | | Elastic | | |
|---|---|---|---|---|---|---|
| Sample | Composition (mol %) | | | modulus | Vitrification | Chemical |
| group | Na₂O | B₂O₃ | SiO₂ | (GPa) | behavior | resistance |
| #1 | 10 | 80 | 10 | 36 | ◯ | XXX |
| | | | | | (M1000, A350) | |
| #2 | 10 | 70 | 20 | — | ◯ | XX |
| | | | | | (M1100, A350) | |
| #3 | 10 | 60 | 30 | — | ◯ | X |
| | | | | | (M1100, A350) | |
| #4 | 10 | 50 | 40 | — | ◯ | Δ |
| | | | | | (M1200, A360) | |
| #5 | 10 | 45 | 45 | 47.1 | ◯ | ◯ |
| | | | | | (M1200, A360) | |
| #6 | 10 | 40 | 50 | 51.2 | ◯ | ◯ |
| | | | | | (M1200, A360) | |
| #7 | 5 | 90 | 5 | — | ◯ | X |
| | | | | | (M1100, A350) | |
| #8 | 5 | 65 | 30 | — | ◯ | X |
| | | | | | (M1100, A360) | |
| #9 | 5 | 60 | 35 | — | ◯ | X |
| | | | | | (M1100, A360) | |
| #10 | 5 | 55 | 40 | — | ◯ | X |
| | | | | | (M1100, A350) | |
| #11 | 5 | 50 | 45 | — | ◯ | X |
| | | | | | (M1200, A360) | |
| #12 | 5 | 45 | 50 | — | ◯ | X |
| | | | | | (M1200, A360) | |
| #13 | 5 | 40 | 55 | 50.2 | ◯ | ◯ |
| | | | | | (M1300, A450) | |
| #14 | 5 | 35 | 60 | 52.7 | ◯ | ◯ |
| | | | | | (M1300, A450) | |

Referring to Table 1 above, it can be seen that SAMPLE #1 through SAMPLE #14 were all capable of vitrification behavior and thus melted well and manufactured into transparent glass articles.

SAMPLE #1 through SAMPLE #4 and SAMPLE #7 through SAMPLE #12 showed low chemical resistance, whereas the glass articles of SAMPLES #5, #6, #13 and #14 showed high chemical resistance, and were entirely transparent to have a transmittance of 88% or higher.

In addition, the elastic moduli of SAMPLES #5, #6, #13, and #14 were 47.1 GPa, 51.2 GPa, 50.2 GPa, and 52.7 GPa, respectively.

In addition, although not shown in Table 1, the glass articles of SAMPLES #5, #6, #13, and #14 were chemically tempered in a molten salt of 100% nitrate at a temperature of 420° C. for 2 hours, and then their compressive stress and compression depth were measured.

SAMPLES #5 and #6 showed a compressive stress of 300 MPa or less and a compression depth of 10 μm or less. SAMPLES #13 and #14 showed a compressive stress of 200 MPa or less and a compression depth of 10 μm or less.

As is apparent from the above results, a glass article manufactured using a ternary glass composition containing SiO₂, B₂O₃, and Na₂O having a composition (in a composition ratio) according to an embodiment has an elastic modulus of 45 to 55 GPa, is capable of vitrification behavior, has excellent chemical resistance, and is easily chemically tempered.

### Experimental Example 2: Manufacture of Quaternary Glass Articles

Glass compositions having a quaternary composition ratio of SiO₂, B₂O₃, Na₂O and Al₂O₃ were prepared according to Table 2 below, and then glass articles of SAMPLE #15 through SAMPLE #26 were manufactured. The glass article of each sample was manufactured to have a thickness of 50 μm.

The composition, elastic modulus, vitrification behavior, density and chemical resistance of the glass article of each sample were measured and are shown in Table 2 below.

TABLE 2

| | | | | | Elastic | | | |
|---|---|---|---|---|---|---|---|---|
| Sample | Composition (mol %) | | | | modulus | Vitrification | Chemical | Density |
| group | Na₂O | Al₂O₃ | B₂O₃ | SiO₂ | (GPa) | behavior | resistance | (g/cm³) |
| #15 | 10 | 5 | 75 | 10 | 32.4 | ◯ | X | 2.06 |
| | | | | | | (M1100, | | |
| | | | | | | A350) | | |
| #16 | 10 | 7.5 | 72.5 | 10 | 34.2 | ◯ | ◯ | 2.08 |
| | | | | | | (M1100, | | |
| | | | | | | A350) | | |
| #17 | 10 | 10 | 70 | 10 | 35.7 | ◯ | ◯ | 2.10 |
| | | | | | | (M1200, | | |
| | | | | | | A350) | | |
| #18 | 10 | 10 | 35 | 45 | — | ◯ | ◯ | — |
| | | | | | | (M1300, | | |
| | | | | | | A450) | | |
| #19 | 10 | 10 | 30 | 50 | — | ◯ | ◯ | — |
| | | | | | | (M1300, | | |
| | | | | | | A450) | | |
| #20 | 10 | 5 | 35 | 50 | — | ◯ | ◯ | — |
| | | | | | | (M1300, | | |
| | | | | | | A450) | | |
| #21 | 10 | 5 | 40 | 45 | — | ◯ | ◯ | — |
| | | | | | | (M1300, | | |
| | | | | | | A450) | | |
| #22 | 10 | 5 | 30 | 55 | — | ◯ | ◯ | — |
| | | | | | | (M1300, | | |
| | | | | | | A450) | | |
| #23 | 5 | 5 | 75 | 15 | — | ◯ | X | — |
| | | | | | | (M1200, | | |
| | | | | | | A360) | | |
| #24 | 5 | 7.5 | 72.5 | 15 | — | ◯ | X | — |
| | | | | | | (M1200, | | |
| | | | | | | A360) | | |
| #25 | 5 | 10 | 70 | 15 | — | ◯ | X | — |
| | | | | | | (M1200, | | |
| | | | | | | A360) | | |
| #26 | 5 | 5 | 30 | 60 | 43.1 | ◯ | ◯ | 2.21 |
| | | | | | | (M1300, | | |
| | | | | | | A450) | | |

Referring to Table 2 above, it can be seen that SAMPLE #15 through SAMPLE #26 were all capable of vitrification behavior and thus melted well and manufactured into transparent glass articles.

SAMPLE #15 and SAMPLE #23 through SAMPLE #25 showed low chemical resistance, whereas the glass articles of SAMPLES #16 through #22 and SAMPLE #26 were entirely transparent and had a transmittance of 88% or higher.

The elastic moduli of SAMPLES #15, #16, #17, and #26 were 32.4 GPa, 34.2 GPa, 35.7 GPa, and 43.1 GPa, respectively. Although not shown in Table 2, the elastic moduli of SAMPLES #18 through #22 were in the range of 35 to 60 Gpa.

The densities of SAMPLES #15, #16, #17, and #26 were 2.06, 2.08, 2.10, and 2.21 grams per cubic centimeters (g/cm³), respectively. Although not shown in Table 2, the densities of SAMPLES #18 through #22 were in the range of 2.1 to 2.4 g/cm³.

In addition, although not shown in Table 2, the glass articles of SAMPLES #16 through #22 and SAMPLE #26 were chemically tempered in a molten salt of 100% nitrate at a temperature of 420° C. for 2 hours, and then their compressive stress and compression depth were measured.

SAMPLES #16 and #17 showed a compressive stress of 200 MPa or less and a compression depth of 7 μm or less. SAMPLES #18 through #22 showed a compressive stress of 500 MPa or less and a compression depth of 10 μm or less. SAMPLE #26 showed a compressive stress of 300 MPa or less and a compression depth of 10 μm or less.

As is apparent from the above results, a glass article manufactured using a quaternary glass composition containing SiO₂, Al₂O₃, B₂O₃, and Na₂O having a composition (in a composition ratio) according to an embodiment has an elastic modulus of 30 to 60 GPa and a density of 2 to 2.4 g/cm³, is capable of vitrification behavior, has excellent chemical resistance, and is easily chemically tempered.

### Experimental Example 3: Manufacture of Quinary Glass Articles

Glass compositions having a quinary composition ratio of SiO₂, B₂O₃, Na₂O, K₂O and Al₂O₃ were prepared according to Table 3 below, and then glass articles of SAMPLE #27 and SAMPLE #28 were manufactured. The glass article of each sample was manufactured to have a thickness of 50 μm.

The composition, vitrification behavior, density and chemical resistance of the glass article of each sample were measured and are shown in Table 3 below.

TABLE 3

| | | | | | | Vitrifica- | |
|---|---|---|---|---|---|---|---|
| Sample | Composition (mol %) | | | | | tion | Chemical |
| group | Na₂O | Al₂O₃ | B₂O₃ | K₂O | SiO₂ | behavior | resistance |
| #27 | 8 | 5 | 40 | 2 | 45 | ◯ | ◯ |
| | | | | | | (M1400, | |
| | | | | | | A400) | |
| #28 | 5 | 10 | 35 | 5 | 45 | ◯ | ◯ |
| | | | | | | (M1400, | |
| | | | | | | A400) | |

Referring to Table 3 above, it can be seen that SAMPLE #27 and SAMPLE #28 were all capable of vitrification behavior and thus melted well and manufactured into transparent glass articles.

The glass articles of SAMPLE #27 and SAMPLE #28 were entirely transparent and had a transmittance of 88% or higher.

Although not shown in Table 3, the elastic moduli of SAMPLE #27 and SAMPLE #28 were in the range of 40 to 50 Gpa.

In addition, although not shown in Table 3, the glass articles of SAMPLE #27 and SAMPLE #28 were chemically tempered in a molten salt of 100% nitrate at a temperature of 420° C. for 2 hours, and then their compressive stress and compression depth were measured.

SAMPLES #27 and #28 showed a compressive stress of 300 MPa or less and a compression depth of 10 μm or less.

As is apparent from the above results, a glass article manufactured using a quinary glass composition containing SiO₂, K₂O, Al₂O₃, B₂O₃, and Na₂O having a composition (in a composition ratio) according to an embodiment has an elastic modulus of 40 to 50 GPa, is capable of vitrification behavior, has excellent chemical resistance, and is easily chemically tempered.

A glass composition according to an embodiment may contain components in a novel composition ratio, and a glass article manufactured from the glass composition may have flexibility due to its low modulus and may have excellent chemical durability. In addition, the glass article may have excellent flexibility to the extent that it can be applied to a foldable display device.

The display device according to one embodiment of the present disclosure can be applied to various electronic devices. The electronic device according to the one embodiment of the present disclosure includes the display device described above, and may further include modules or devices having additional functions in addition to the display device.

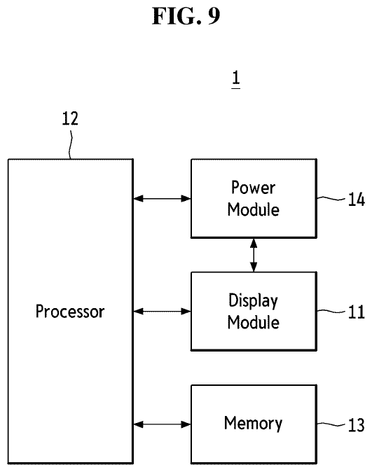

FIG. 9 is a block diagram of an electronic device according to one embodiment of the present disclosure.

Referring to FIG. 9, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 1 according to the one embodiment of the present disclosure may be included in the display device 500 according to the embodiments of the present disclosure. In addition, some modules of the individual modules functionally included in one module may be included in the display device 500, and other modules may be provided separately from the display device 500. For example, the display device 500 may include the display module 11, and the processor 12, the memory 13, and the power module 14 may be provided in the form of other devices within the electronic device 1 other than the display device 500.

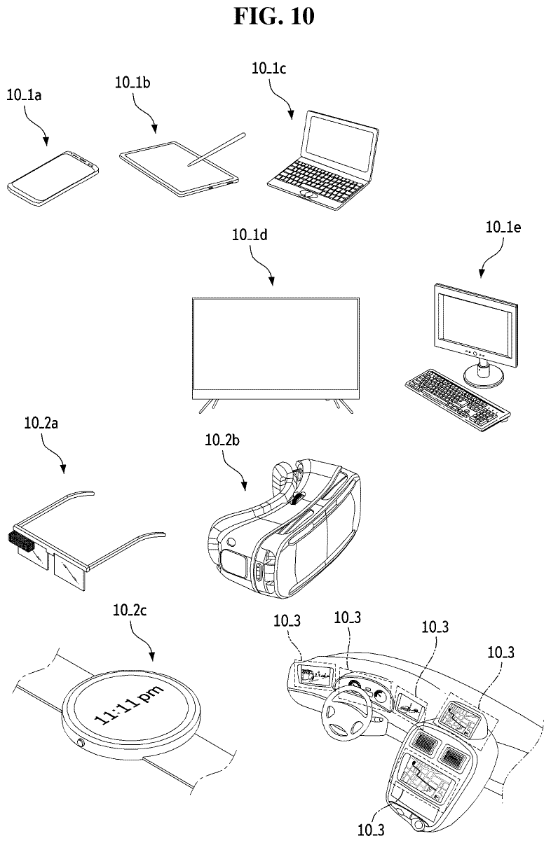

FIG. 10 is a schematic diagram of an electronic device according to various embodiments of the present disclosure.

Referring to FIG. 10, various electronic devices to which display devices 500 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A glass article comprising, as a glass composition:
45 to 60 mole percents (mol %) SiO₂,
greater than 35 and equal to or less than 45 mol % B₂O₃,
3 to less than 9 mol % Na₂O, and
greater than 0 to less than 8 mol % Al₂O₃ based on total content of the glass article.

2. The glass article of claim 1, wherein a difference between the B₂O₃ content and the Na₂O content is 40 mol % or less.

3. The glass article of claim 1, wherein a ratio of the Na₂O content to the Al₂O₃ content is greater than 1.

4. The glass article of claim 1, further comprising K₂O in an amount of greater than 0 to 5 mol %.

5. The glass article of claim 4, wherein a ratio of a sum of the Na₂O content and the K₂O content to the Al₂O₃ content is greater than 1.

6. The glass article of claim 1, wherein a thickness of the glass article is 50 to 100 micrometers (μm).

7. The glass article of claim 1, wherein an elastic modulus of the glass article is 30 to 55 gigapascals (GPa).

8. A display device comprising:
a display panel comprising a plurality of pixels;
a cover window located on the display panel; and
an optically clear bonding layer located between the display panel and the cover window,
wherein the cover window comprises, as a glass composition, 45 to 60 mol % SiO₂, greater than 35 and equal to or less than 45 mol % B₂O₃, 3 to less than 9 mol % Na₂O, and greater than 0 to less than 8 mol % Al₂O₃ based on total content of the cover window.

9. The display device of claim 8, wherein a difference between the B₂O₃ content and the Na₂O content is 40 mol % or less.

10. The display device of claim 8, wherein a ratio of the Na₂O content to the Al₂O₃ content is greater than 1.

11. The display device of claim 8, further comprising K₂O in an amount of greater than 0 to 5 mol %.

12. The display device of claim 11, wherein a ratio of a sum of the Na₂O content and the K₂O content to the Al₂O₃ content is greater than 1.

13. The display device of claim 8, wherein the cover window has a thickness of 50 to 100 μm.

14. The display device of claim 8, wherein the cover window has an elastic modulus of 30 to 55 GPa.

15. An electronic device, comprising:
a display device configured to provide an image; and
a processor configured to provide an image data signal to the display device, and
wherein the display device comprises:
a display panel comprising a plurality of pixels;
a cover window located on the display panel; and
an optically clear bonding layer located between the display panel and the cover window,
wherein the cover window comprises, as a glass composition, 45 to 60 mol % SiO₂, greater than 35 and equal to or less than 45 mol % B₂O₃, 3 to less than 9 mol % Na₂O, and greater than 0 to less than 8 mol % Al₂O₃ based on total content of the cover window.

16. The electronic device of claim 15, wherein a difference between the B₂O₃ content and the Na₂O content is 40 mol % or less.

17. The electronic device of claim 15, wherein a ratio of the Na₂O content to the Al₂O₃ content is greater than 1.

18. The electronic device of claim 15, further comprising K₂O in an amount of greater than 0 to 5 mol %.

19. The electronic device of claim 18, wherein a ratio of a sum of the Na₂O content and the K₂O content to the Al₂O₃ content is greater than 1.

20. The electronic device of claim 15, wherein the cover window has a thickness of 50 to 100 μm.
